(19) United States
(12) Patent Application Publication
(10) Pub. No.: US 2012/0237682 A1
(43) Pub. Date: Sep. 20, 2012

(54) IN-SITU MASK ALIGNMENT FOR DEPOSITION TOOLS

(75) Inventors: Ilyoung Richard Hong, San Jose, CA (US); William N. Sterling, Santa Clara, CA (US); Dongsuh Lee, Santa Clara, CA (US)

(73) Assignee: Applied Materials, Inc., Santa Clara, CA (US)

(21) Appl. No.: 13/414,434

(22) Filed: Mar. 7, 2012

Related U.S. Application Data
(60) Provisional application No. 61/454,391, filed on Mar. 18, 2011.

(51) Int. Cl. B05D 1/32; B05C 11/00; B23Q 7/00; B05C 13/00

(52) U.S. Cl. 427/282; 118/500; 118/712; 29/407.09

(57) ABSTRACT

A system for handling masked substrates comprising a chamber having a pedestal for supporting a substrate, and a chuck for supporting a mask in relation to a substrate. The system may include an alignment system operable to confirm alignment of the mask and the substrate. A method of positioning a mask on a substrate in a chamber comprises supporting the mask with a chuck disposed in the chamber and supporting the substrate with a pedestal disposed in the chamber. The method may further comprise aligning one or more reference points on the mask with one or more reference points on the substrate and positioning the mask on the substrate using at least one of the chuck and the pedestal.

### CROSS-REFERENCE TO RELATED APPLICATION

This application claims benefit of U.S. Provisional Application Ser. No. 61/454,391, filed Mar. 18, 2011, the contents of which are herein incorporated by reference in their entirety.

### BACKGROUND

1. Field of the Invention

Embodiments of the invention relate to a substrate mask handling and processing system.

2. Description of the Related Art

Organic light emitting diodes (OLED) are used in the manufacture of television screens, computer monitors, mobile phones, etc. for displaying information. A typical OLED may include layers of organic material situated between two electrodes that are all deposited on a substrate in a manner to form a matrix display panel having individually energizable pixels. The OLED is generally placed between two glass panels, and the edges of the glass panels are sealed to encapsulate the OLED therein.

There are many challenges encountered in the manufacture of such display devices. In one example, there are numerous labor intensive steps necessary to encapsulate the OLED between the two glass panels to prevent possible contamination of the device. In another example, different sizes of display screens and thus glass panels may require substantial reconfiguration of the process and process hardware used to form the display devices.

Therefore, there is a continuous need for new and improved apparatus and methods for forming OLED display devices.

### SUMMARY

In one embodiment, a system for handling masked substrates comprises a chamber having a pedestal for supporting a substrate, and a chuck for supporting a mask in relation to a substrate; and an alignment system operable to confirm alignment of the mask and the substrate.

In one embodiment, a method of positioning a mask on a substrate in a chamber comprises supporting the mask with a chuck disposed in the chamber; supporting the substrate with a pedestal disposed in the chamber; aligning one or more reference points on the mask with one or more reference points on the substrate; and positioning the mask on the substrate using at least one of the chuck and the pedestal.

In one embodiment, a method of handling a mask and a substrate comprises positioning the mask on the substrate in a first chamber; processing the substrate while the mask is positioned on the substrate in a second chamber; removing the mask from the substrate after processing the substrate in a third chamber; positioning the mask on a carrier in the third chamber; and cleaning the mask on the carrier in a fourth chamber.

### BRIEF DESCRIPTION OF THE DRAWINGS

So that the manner in which the above recited features can be understood in detail, a more particular description of embodiments of the invention, briefly summarized above, may be had by reference to the embodiments, some of which are illustrated in the appended drawings. It is to be noted, however, that the appended drawings illustrate only typical embodiments and are therefore not to be considered limiting of its scope, for the invention may admit to other equally effective embodiments.

FIG. 1 illustrates a system for forming OLED devices according to one embodiment.

FIG. 2 illustrates a chamber of the system according to one embodiment.

FIG. 3 illustrates another chamber of the system according to one embodiment.

FIG. 4 illustrates another system for forming OLED devices according to one embodiment.

FIG. 5A illustrates a mask and a carrier according to one embodiment.

FIG. 5B illustrates a mask according to one embodiment.

FIG. 6A illustrates a mask and a substrate according to one embodiment.

FIG. 6B illustrates a mask according to one embodiment.

FIG. 7 illustrates a mask and a substrate according to one embodiment.

### DETAILED DESCRIPTION

Embodiments of the invention may include a process of forming an OLED device, and in particular a process of using chemical vapor deposition to encapsulate an OLED-based substrate. The process may include accurately aligning and positioning a mask on the substrate to mask certain areas of the substrate while enabling access to the exposed or unmasked regions of the substrate, performing a process to effect a change at the exposed surfaces of the substrate, for example deposition of a material thereon by chemical vapor deposition and/or physical vapor deposition, and thereafter separating the mask and the processed substrate. The mask may be supported on a carrier when removed from the substrate. The substrate may then be further processed and/or separated into individual devices to form one or more OLED devices.

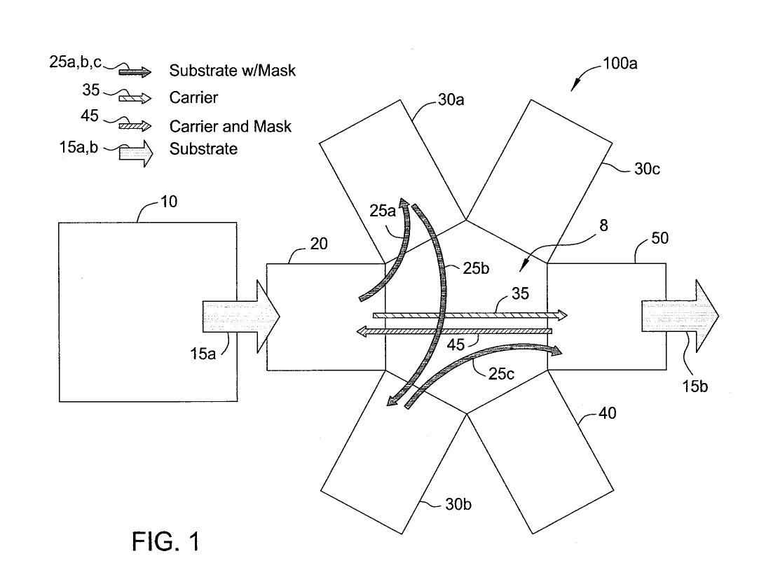

FIG. 1 illustrates a system 100a for forming an OLED device according to one embodiment. The system 100a may include a deposition chamber 10, an alignment chamber 20, encapsulation chambers 30a, 30b, 30c, an optional chamber 40, and a removal chamber 50 all clustered around, and selectively vacuum isolated with respect to, a transfer chamber 8. In this embodiment, the deposition chamber 10 may be configured to create one or more OLED devices on a substrate, and the substrate, with one or more devices thereon, may then be transported via the transfer chamber to one or more additional chamber locations for processing. Deposition chamber 10 may be, for example, a single deposition chamber coupled to a transfer chamber, a final process region, or a process chamber, in an in-line deposition tool wherein an OLED device is fabricated on the substrate, a plurality of in-line deposition chambers coupled to a separate transfer chamber at the end thereof distal from the alignment chamber 20 and/or the transfer chamber 8, a device isolation chamber, such as an etch or laser isolation chamber wherein individual OLED devices are physically isolated from one another in-situ on the substrate, or a substrate loading station, wherein substrates having an OLED device fabricated thereon in a tool(s) which are not physically attached to the alignment chamber 20 and/or the transfer chamber 8 may be loaded for encapsulation processing using the system 100a.

In one embodiment, the substrate may be a glass substrate with an OLED formed or positioned on the glass substrate. The alignment chamber 20 may be configured to align and position a mask on the substrate. The mask is used as a partition to divide the substrate into one or more sections during processing. The mask is supported on a carrier when it is removed from the substrate. The encapsulation chambers 30a, 30b, 30c may be configured to encapsulate (via chemical vapor deposition for example) portions of the substrate that are exposed through the mask. The optional chamber 40 also may be configured as an encapsulation chamber, or may be used as a storage and/or cleaning chamber to store and clean the masks. Finally, the removal chamber 50 may be configured to physically remove the mask from the encapsulated substrate so that the mask can be reused for further encapsulation processes. The encapsulated or processed substrate may be removed from the system 100a through the removal chamber 50 for further processing with one or more other systems.

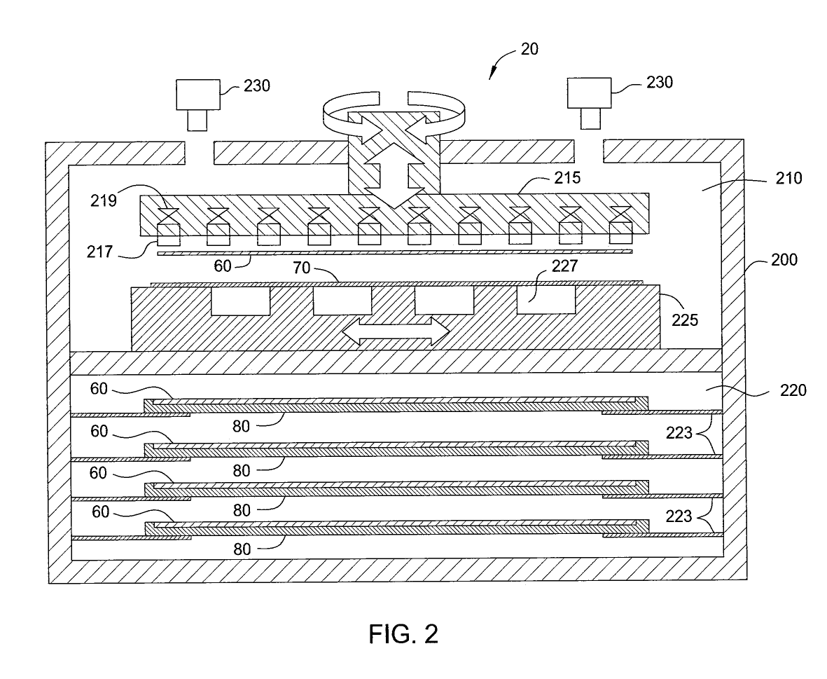

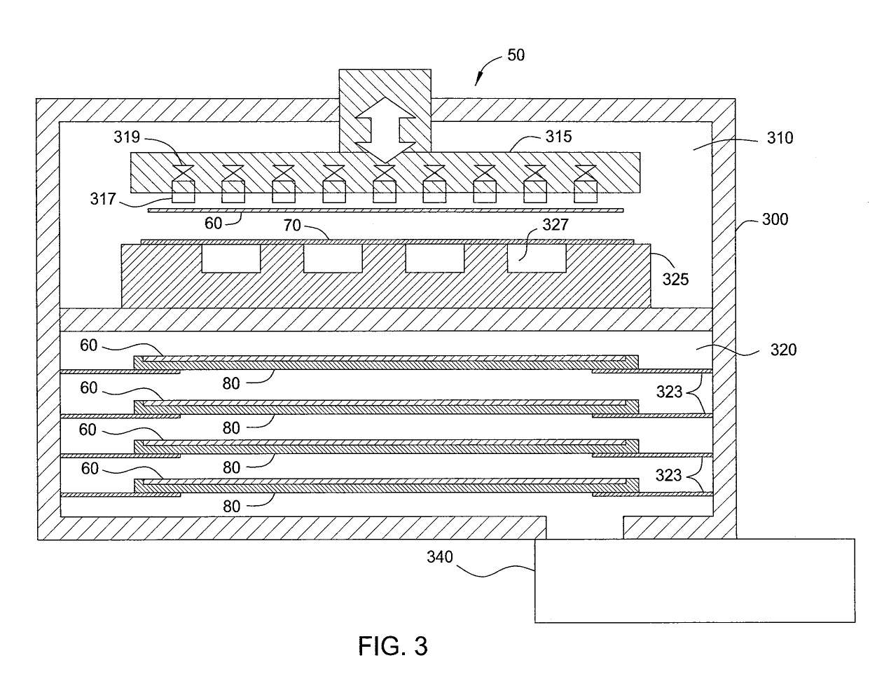

The reference arrows identified with reference numerals 15a, 15b, 25a, 25b, 25c, 35, 45 generally illustrate the relative travel paths of the substrate, mask, and carrier throughout a process of use with the system 100a according to one embodiment. The system 100a may be configured with one or more robotic arms or other similar handling mechanisms located in and extendable from transfer chamber 8 for moving the substrate, mask, and mask carrier between the chambers of the system 100a. An OLED initially may be created in the deposition chamber 10 on a substrate. The substrate may then be moved into the alignment chamber 20 as illustrated by reference arrow 15a. Prior to introduction of the substrate into the alignment chamber 20, a mask and a carrier that supports the mask are moved into the alignment chamber 20, as illustrated by reference arrow 45 for example. The mask and carrier may be stored in and retrieved from a storage compartment of the alignment chamber 20 or the removal chamber 50 (each of which are further described below with respect to FIGS. 2 and 3, respectively). Once positioned in the alignment chamber 20, the mask is removed from the carrier via a chuck or other similar handling mechanism, and the carrier is returned to and stored in the storage compartment of the alignment chamber 20 or the removal chamber 50 as illustrated by reference arrow 35. In one embodiment, the substrate may be moved into the alignment chamber 20 prior to the mask and the carrier being moved therein.

After the substrate is located within the alignment chamber 20, the mask may be accurately aligned over the substrate and positioned on top of the substrate using an alignment mechanism in combination with the chuck or other handling mechanism. The masked substrate may then be moved to one or more of the encapsulation chambers 30a, 30b, 30c and/or the optional chamber 40 to encapsulate the substrate via one or more processes. As illustrated, the masked substrate first is moved from the alignment chamber 20 to the encapsulation chamber 30a, indicated by reference arrow 25a, and then from the encapsulation chamber 30a to the encapsulation chamber 30b indicated by reference arrow 25b. Subsequently, the masked substrate is moved from the encapsulation chamber 30b to the removal chamber 50 indicated by reference arrow 25c. When in the removal chamber 50, the mask may be removed from the substrate via a chuck or other handling mechanism, and the substrate may be removed from the removal chamber 50 as illustrated by reference arrow 15b. While the mask is being supported in the removal chamber 50, a carrier may be moved into the removal chamber 50 and the mask may be aligned and positioned on the carrier. The mask and the carrier may be stored and/or cleaned in a storage/cleaning chamber of the removal chamber 50 for use with another substrate encapsulation process. In one embodiment, the removal chamber 50 may be configured as another encapsulation chamber, and the processed substrate may be removed through the deposition chamber 10 via the alignment chamber 20. In one embodiment, one or more substrates, masks, and carriers may be used concurrently with the system 100a to process multiple substrates.

FIG. 2 illustrates an alignment chamber 20 of the system 100a according to one embodiment. The alignment chamber 20 includes a chamber body 200 that is divided into an upper chamber 210 and a lower chamber 220. The lower chamber 220 may be used to store one or more masks 60 supported on one or more carriers 80. The masks 60 and carriers 80 may be stored on one or more support members 223 in the form of opposed truncated shelves. In one embodiment, the lower chamber 220 may include any number of support members 223 to support four, six, or more masks 60 and carriers 80. While stored in the lower chamber 220, the masks 60 and the carriers 80 may be cleaned for use in subsequent substrate deposition processes. At least one mask 60 that is supported by at least one carrier 80 may be moved from the lower chamber 220 to the upper chamber 210 via a robotic arm or other handling mechanism for further processing as described above with respect to FIG. 1. In one embodiment, the upper chamber 210 may include one or more openings or doors in communication with the deposition chamber 10 for receiving substrates. The upper chamber 210 may also include one or more openings or doors in communication with the transfer chamber 8 from which the robotic arm or other handling mechanism may introduce the mask and carrier and/or may retrieve the masked substrates and carriers. In one embodiment, the lower chamber 220 may also include one or more openings or doors in communication with the transfer chamber 8 from which the robotic arm or other handling mechanism may introduce and retrieve the masks and/or carriers. In one embodiment, the robotic arm or other handling mechanism may be moveable in both the vertical and horizontal directions to move the substrates, masks, and/or carriers between the upper and lower chambers 210, 220 of alignment chamber 20, as well as the other chambers 30a, 30b, 30c, 40, 50.

The lower chamber 220 may be configured to store and/or clean the masks, which may have been used in multiple deposition processes. The lower chamber 220 may also provide a mechanism of mask change caused by product change or damaged/end of life masks without impacting throughput of the system 100a. For example, different types and/or sizes of masks may be used with the system 100a to accommodate different types and/or sizes of substrates and/or deposition processes.

The upper chamber 210 may be configured with a pedestal 225 for supporting both carriers 80 (and masks 60) and as illustrated substrates 70. In one embodiment, the pedestal 225 may be provided with linear or axial motion capabilities (e.g. up to 3 degrees of freedom including x and y axial movement to aid in alignment of the mask with the substrate, and z-motion for interaction with a robot for placing and removing substrates with respect thereto). The pedestal 225 may be configured with permanent magnets and/or electromagnets. The pedestal 225 may further include one or more pockets 227 into which end effectors of a robot arm may be moved to locate the carriers 80 and the substrates 70 onto the pedestal 225. In this manner, the pedestal 225 may be operable to support the substrates 70 while the masks 60 are positioned on the substrates 70, and may be operable to support the carriers 80 while the masks 60 are removed from the carriers 80.

The upper chamber 210 is configured with a chuck 215 for supporting the masks 60 for removal and placement of the masks on the substrates. In one embodiment, the chuck 215 may be an electromagnetic chuck and/or vacuum chuck with rotational and linear or axial motion capabilities (e.g. up to 3 degrees of freedom including x, y, z axial movement). The chuck 215 may further include one or more electromagnets 217, or alternatively one or more vacuum cups, that are configured to engage and lift the mask 60 from the carrier 80 for example. The surfaces of the vacuum cups or electromagnets 217 that contact the mask 60 may be coated with a soft material, such as polytetrafluoroethylene or Teflon, to minimize potential damage to the mask 60, such as to prevent surface abrasion of the mask 60. The vacuum cups or electromagnets 217 may also be biased by one or more springs 219 to provide a range of compliancy between the vacuum cups or electromagnets 217 and the masks 60 to further minimize potential damage to the masks 60 when initially engaging the masks 60 from above. In one embodiment, the chuck 215 may be configured to generate a pressure differential sufficient to engage and lift the mask 60 from the carrier 80. In one embodiment, the chuck 215 may include an array of strips of magnetic material that are electrically magnetized to lift the mask 60 from the carrier 80. In one embodiment, the chuck 215 may include an array of strips with a series of vacuum suction holes to lift the mask 60 from the carrier 80. In this manner, the chuck 215 may be operable to lift the mask 60 from the carrier 80, hold the mask 60 while the carrier 80 is removed and the substrate 70 is introduced into the upper chamber 210, and lower the mask 60 onto the substrate 70, and/or perform this sequence to remove the mask 60 from the substrate 70 if necessary.

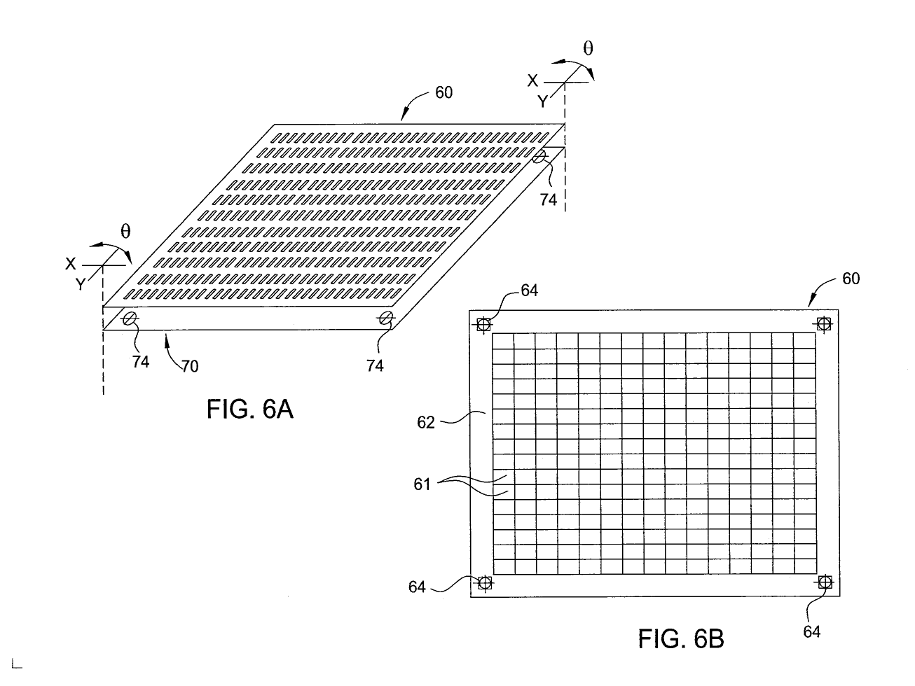

The alignment chamber 20 further may be configured with an alignment system 230 to assist with the alignment of the mask 60 and the substrate 70. In one embodiment, the alignment system 230 may include a vision system having one or more cameras to provide a visual indication of the alignment between the mask 60 and the substrate 70. In one embodiment, the masks 60 and the substrates 70 may include one or more alignment or reference points (as shown in FIGS. 6A and 6B) to facilitate accurate alignment of the mask 60 on the substrate 70. In one embodiment, the cameras of the alignment system 230 may be used to provide a visual indication and confirmation if and when the reference points on the masks 60 and the substrates 70 are aligned. When the respective mask 60 and substrate 70 are aligned, the chuck 215 may lower the mask 60 onto the substrate 70. Using the reference points, the alignment system 230, and the motion capabilities of the chuck 215 and/or the pedestal 225, the masks 60 may be accurately aligned and positioned on the substrates 70. In one embodiment, the masks 60 may be aligned relative to the substrates 70 within about a 100 μm range of accuracy. The masked substrate 70 may then be moved to one or more encapsulation chambers 30a, 30b, 30c for further processing as described above with respect to FIG. 1. In one embodiment, the alignment chamber 20 may also be configured as a deposition chamber, such as deposition chamber 10 and/or encapsulation chambers 30a, 30b, 30c, for performing one or more deposition processes on the masked substrate in addition to the alignment process.

In one embodiment, aligning the mask relative to the substrate may be accomplished using one or more (multiple) cameras of the alignment system 230. In one embodiment, at least three cameras may be used. The reference points on the mask and substrate may be marked with mating alignment marks. The mask may be moved into the alignment chamber 20 and lifted by the chuck 215, the carrier may be removed, and then a substrate may be moved into the alignment chamber 20. In one embodiment, the substrate may first be moved into the alignment chamber 20 and positioned on the pedestal 225, and then a mask on a carrier may be moved into the alignment chamber 20 so that the chuck 215 may lift the mask from the carrier while being supported by the robotic arm or other handling mechanism. The cameras may optically locate the reference points on the mask and/or the substrate. The alignment system 230 may accurately calculate the position and/or differences in the reference point positions on the mask and/or the substrate in relation to a fixed coordinate system. The positions and/or differences in positions of the mask and the substrate may be compared and analyzed to then communicate directional coordinates to the chuck 215 and/or pedestal 225. Based on the direction from the alignment system 230, the chuck 215 and/or pedestal 225 may be operated manually, remotely, and/or automatically to move the mask and/or the substrate to match and align the reference points. In one embodiment, the pedestal 225 may move the substrate in the x-plane, the y-plane, and rotationally within the x-y plane to align the substrate with the mask. In one embodiment, the chuck 215 may move the mask in the x-plane, the y-plane, and rotationally within the x-y plane to align the mask with the substrate. Both the substrate and the mask can be moved for alignment. The mask and/or substrate may then be moved closer to each other in the z-plane via the chuck 215 and/or pedestal 225, and the alignment system 230 may validate the alignment between the reference points prior to placing the mask on the substrate.

FIG. 3 illustrates a removal chamber 50 of the system 100a according to one embodiment. The removal chamber 50 may be substantially similar to the alignment chamber 20. The similar features are identified with the same reference numerals except having a “300” series designation, such as the body 300, the springs 319, and the pockets 327 for example. The embodiments of the alignment chamber 20 may be used with the embodiments of the removal chamber 50 and vice versa. As illustrated, the chuck 315 may be operable to remove the mask 60 from the substrate 70, and may be operable to position the mask 60 on a carrier 80, the carrier 80 being placed under the mask 60 by the robot when the mask 60 has been lifted and secured from the substrate 70. In one embodiment, the pedestal 325 may be fixed (non-movable), and the chuck 315 may be movable in the vertical direction. In this embodiment, if the substrate 70 is to be left on the pedestal 325, the robot may have vertical or z-axis motion capability. A cleaning system 340 may be coupled to or in communication with the lower chamber 320 where the masks 60 supported on the carriers 80 are stored. While stored in the lower chamber 320, the cleaning system 340 may be activated to clean the masks 60 and the carriers 80 for use in subsequent substrate deposition processes. In one embodiment, the cleaning system may include a remote plasma source chamber, a gas panel, a pump, and/or other components for cleaning the masks 60 and carriers 80. In one embodiment, the upper and lower chambers 310, 320 may each include one or more openings or doors in communication with the transfer chamber 8 from which the robotic arm or other handling mechanism may introduce and retrieve the substrates, masks, and/or mask carriers. In one embodiment, the upper chamber 310 may also include one or more openings or doors opposite the transfer chamber 8 from which the substrates may be removed from the system 100a. In one embodiment, the robotic arm or other handling mechanism may be moveable in both the vertical and horizontal directions to move the substrates, masks, and/or carriers between the upper and lower chambers 310, 320 of removal chamber 50, as well as the other chambers 20, 30a, 30b, 30c, 40.

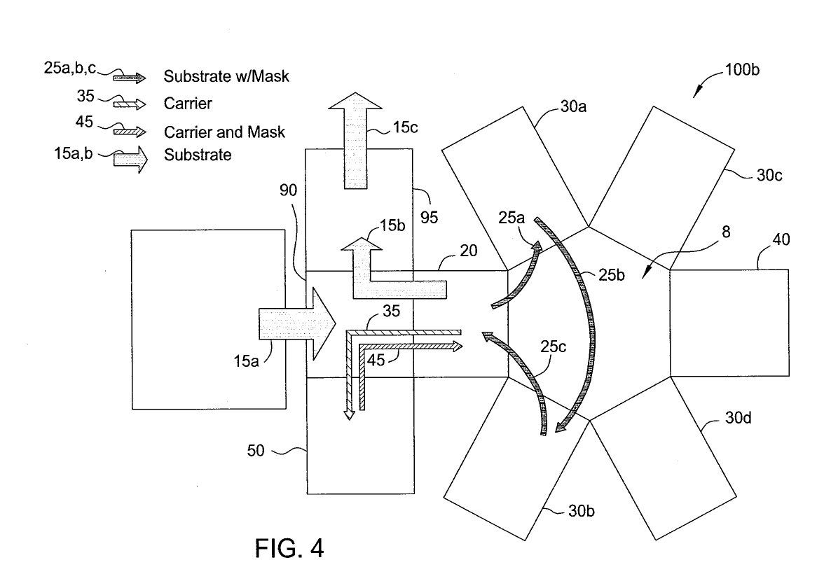

FIG. 4 illustrates a system 100b for forming an OLED device according to one embodiment. The system 100b may be substantially similar to the system 100a. The similar features are identified with the same reference numerals. The embodiments of the system 100b may be used with the embodiments of the system 100a and vice versa. In one embodiment, one or more of the processes described herein with respect to the systems 100a and 100b may be repeated and/or performed in any order.

The system 100b may include a deposition chamber 10, a pass-thru chamber 90, an alignment chamber 20, encapsulation chambers 30a, 30b, 30c, 30d, an optional chamber 40, a removal chamber 50, and an exit chamber 95. In one embodiment, the deposition chamber 10, the alignment chamber 20, the encapsulation chambers 30a, 30b, 30c, the optional chamber 40, and the removal chamber 50 may be the same chambers as described above with respect to the system 100a. The system 100b may further include an additional encapsulation chamber 30d similar to the encapsulation chambers 30a, 30b, 30c. The optional chamber 40 may be configured as an encapsulation chamber, may be used as a storage and/or cleaning chamber to store and clean the masks, or may be used as a removal chamber 50 to remove the masks 60 from the substrates 70 and allow removal of the substrates 70 from the system 100b. In one embodiment, with reference to FIG. 3, the removal chamber 50 may be configured as a storage and cleaning chamber only, such that the chuck 315 and pedestal 325 are removed, and the upper chamber 310 includes one or more support members 323 in the form of truncated shelves for storing the masks 60 and carriers 80, while the lower chamber 320 also includes one or more support members 323 in the form of truncated shelves with the cleaning system 340 operable to clean the masks 60 and carriers 80. In one embodiment, the alignment chamber 20, encapsulation chambers 30a, 30b, 30c, 30d, and optional chamber 40 are clustered around, and selectively vacuum isolated with respect to, a transfer chamber 8. In one embodiment, the deposition chamber 10, the alignment chamber 20, the removal chamber 50, and the exit chamber 95 are clustered around, and selectively vacuum isolated with respect to, the pass-thru chamber 90. The reference arrows identified with reference numerals 15a, 15b, 15c, 25a, 25b, 25c, 35, 45 generally illustrate the relative travel paths of the substrates, masks, and carriers throughout a process of use with the system 100b according to one embodiment. The system 100b may be configured with one or more robotic arms or other similar handling mechanisms located in and extendable from transfer chamber 8 for moving the substrates, masks, and mask carriers between the chambers of the system 100b. The system 100b may be configured with one or more robotic arms or other similar handling mechanisms located in and extendable from the pass-thru chamber 90 for moving the substrates, masks, and mask carriers between the chambers of the system 100b. An OLED initially may be created in the deposition chamber 10 on a substrate. The substrate may then be moved through the pass-thru chamber 90 and into the alignment chamber 20 as illustrated by reference arrow 15a. Prior to introduction of the substrate into the alignment chamber 20, a mask and a carrier that supports the mask are moved into the alignment chamber 20, as illustrated by reference arrow 45 for example. The mask and carrier may be stored in and retrieved from the removal chamber 50. Once positioned in the alignment chamber 20, the mask is removed from the carrier via a chuck or other similar handling mechanism (such as chucks 215, 315 described above), and the carrier is returned to and stored in the removal chamber 50 as illustrated by reference arrow 35.

After the substrate is located within the alignment chamber 20, the mask may be accurately aligned over the substrate and positioned on top of the substrate using an alignment mechanism (such as alignment system 230 described above) in combination with the chuck or other handling mechanism. The masked substrate may then be moved to one or more of the encapsulation chambers 30a, 30b, 30c, 30d and/or the optional chamber 40 to encapsulate the substrate via one or more processes. As illustrated, the masked substrate first is moved from the alignment chamber 20 to the encapsulation chamber 30a, indicated by reference arrow 25a, and then from the encapsulation chamber 30a to the encapsulation chamber 30b indicated by reference arrow 25b. Subsequently, the masked substrate is moved from the encapsulation chamber 30b back to the alignment chamber 20 indicated by reference arrow 25c. When in the alignment chamber 20, the mask may be removed from the substrate via the chuck or other handling mechanism, and the substrate may be removed from the alignment chamber 20 to the exit chamber 95 via the pass-thru chamber 90 as illustrated by reference arrow 15b. Once in the exit chamber 95, the substrate may be removed from the system 100b as illustrated by reference arrow 15c. While the mask is being supported in the alignment chamber 20, a carrier (from the removal chamber 50) may be moved into the alignment chamber 20 and the mask may be aligned and positioned on the carrier. The mask and the carrier may be stored and/or cleaned in a storage/cleaning chamber of the removal chamber 50 for use with another substrate encapsulation process. In one embodiment, one or more substrates, masks, and carriers may be used concurrently with the system 100b to process multiple substrates. In one embodiment, the alignment chamber 20 may comprise an upper chamber (such as upper chamber 210) only having one or more doors in communication with the pass-thru chamber 90 and one or more doors in communication with the transfer chamber 8 from which the robotic arms or other handling mechanisms may introduce and remove the substrates, masks and/or carriers. In one embodiment, the removal chamber 50 may include upper and lower chambers (such as chambers 220, 320), and each chamber may have one or more doors in communication with the pass-thru chamber 90 from which the robotic arm or other handling mechanism may introduce and retrieve the masks and/or carriers. In one embodiment, the exit chamber 95 may include only one chamber having one or more doors in communication with the pass-thru chamber 90 from which the robotic arm or other handling mechanism may introduce substrates, and one or more doors opposite the pass-thru chamber 90 to remove the substrates from the system 100b. In one embodiment, the robotic arms or other handling mechanisms may be moveable in both the vertical and horizontal directions to move the substrates, masks, and/or carriers between the chambers of the system 100b. In one embodiment, to ensure the accuracy of mask alignment, magnetic forces can be used to hold the masks and substrates together. This can be achieved using permanent and/or electromagnets on the pedestals 225, 325, as well as the robotic arms.

In one embodiment, a single mask may be re-used one or more times on different substrates for encapsulation processing without having to be cleaned after each process. In this manner, while the mask is being supported in the alignment chamber 20, rather than a carrier (from the removal chamber 50) being brought into the alignment chamber 20 to remove the mask, another substrate (from the deposition chamber 10) may be moved into the alignment chamber 20 and the mask may be accurately aligned and positioned on the substrate. The newly masked substrate may then be move through one or more of the encapsulation chambers 30a, 30b, 30c, 30d and/or optional chamber 40 as described above.

In one embodiment, the masks 60 and/or carriers 80 may be cleaned within the encapsulation chambers 30a, 30b, 30c, 30d (and optional chamber 40 when used for deposition processing) simultaneously when the chambers themselves are cleaned after each deposition process. The chambers may include conventional “shadow frame” or truncated shelves upon which the carriers 80 and masks 60 may be positioned during the cleaning of the chambers. This dual cleaning option provides a significant advantage in that two cleaning processes can be achieved in one step and in particular one chamber.

In one embodiment, the encapsulation chambers may be processing chambers for performing various deposition processes on the substrate. In one embodiment, any one of the chambers described herein may include openings or doors, preferably valved, on opposite sides of the chamber body to allow substrates, masks, and/or carriers to be moved into the chamber from a first side and removed from the chamber on a second opposite side. In one embodiment, any one of the chambers described herein may be operable similar to conventional load lock chambers to introduce and remove substrates, masks, and/or carriers into and from the chambers under pressure controlled, vacuum environments to prevent contamination of the substrates, masks, carriers, and/or chambers. In one embodiment, any type of handling mechanisms, such as a vacuum robot for example, may be used to move the substrates, masks, and/or carriers into and out of the chambers under pressure controlled, vacuum environments to prevent contamination of the substrates, masks, carriers, and/or chambers.

In one embodiment, the systems 100a and/or 100b may be configured to process and output about 1 to about 10 substrates per hour, about 10 to about 20 substrates per hour, about 20 to about 40 substrates per hour, and about 40 to about 100 substrates per hour. The systems 100a and/or 100b provide the advantages of spatially compact systems for processing multiple OLED substrates using a mechanical mask. The systems 100a and/or 100b also provide the advantages of accurate alignment of masks on OLED substrates, as well as efficient handling, removing, storing, and cleaning of the masks in single compact processing systems.

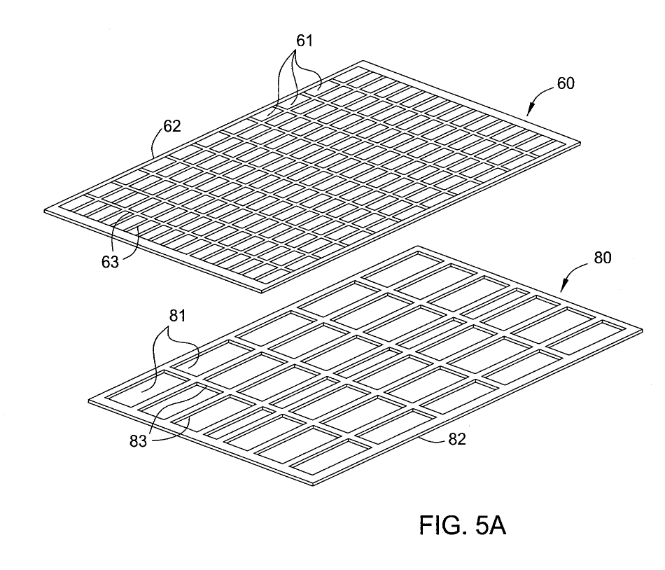

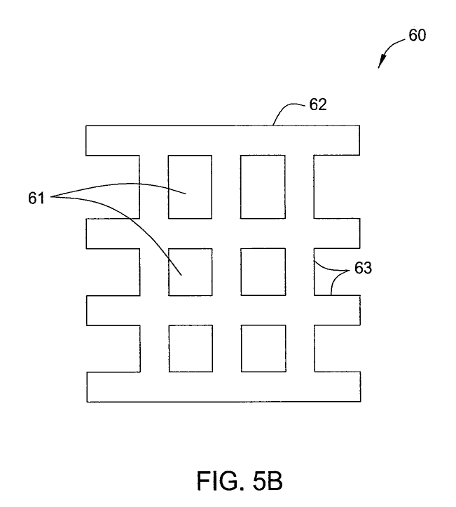

FIGS. 5A and 5B illustrate embodiments of a mask 60 having a plurality of openings 61 formed by a plurality of longitudinal and cross members 63 and surrounded by a border 62. In one embodiment, each mask 60 may include a “picture frame” type design such that the border 62 encloses the openings 61 and the longitudinal and cross members 63 on each side of the mask 60, as illustrated in FIG. 5A. In one embodiment, each mask 60 may include a “frame-less” type design such that the mask 60 includes a border 62 only at the side edges of the mask 60 and does not enclose the outermost openings 61 or the ends of the longitudinal or cross members 63 as illustrated in FIG. 5B. The border 62 at the side edges of the mask 60 may be provided for engagement by the chucks 215, 315. The advantages of a “frame-less” type mask design include smaller mask sizes, less expensive masks, and a simpler construction that requires little or no welding. The systems 100a, 100b are operable with frame and/or frame-less type masks. In one embodiment, the masks 60 may be formed from a magnetic material. In one embodiment, the masks 60 may comprise thin sheets of a metallic material. In one embodiment, the masks 60 may be formed from a nickel steel alloy, such as an Invar material. The Invar material mask may be coated with another material to protect the Invar from corrosion during cleaning of the masks 60. In one embodiment, the Invar material mask may be coated with a Teflon-type material to protect the Invar from corrosion during cleaning of the masks 60. In one embodiment, the masks 60 may be formed from a material having similar thermal expansion properties of solid glass. Each mask 60 may be formed from a single piece of material or may be formed from multiple pieces of material that are joined together, such as by welding using stick, butt, tack or spot welding methods. In one embodiment, each mask 60 may be less than 1 mm in thickness. In one embodiment, each mask 60 may have a thickness of less than about 1 mm or about 0.5 mm. In one embodiment, each mask 60 may be greater than about 0.5 m in length by 0.5 m in width. In one embodiment, each opening 61 of the masks 60 may be about 3 inches in width by about 5 inches in height, but may be dependent on the final product dimensions. In one embodiment, each longitudinal and cross member 63 may be about 2 mm wide. In one embodiment, the border 62 may be about 15 mm wide. The masks 60 may be operable in temperatures up to 100 degrees Celsius. In one embodiment, the sizes and shapes of the masks may be dependent on the final product dimensions.

FIG. 5A also illustrates one embodiment of a carrier 80 having a plurality of openings 81 formed by a plurality of longitudinal and cross members 83 that are surrounded by a border 82. In one embodiment, the carrier 80 may be any type of support structure that can be used to support the masks 60. In one embodiment, the carriers 80 may be formed from a non-magnetic material. In one embodiment, the carriers 80 may comprise thin sheets of a metallic material. In one embodiment, the carriers 80 may be formed from an aluminum alloy. Each carrier 80 may be formed from a single piece of material or may be formed from multiple pieces of material that are joined together, such as by welding. In one embodiment, each carrier 80 may be light weight but with sufficient stiffness (such as configured with longitudinal and cross members 83 or “ribs” to stiffen the carriers 80) to support the masks 60, and may be geometrically compatible with the chuck and pedestals described above.

FIGS. 6A and 6B illustrate a mask 60 and a substrate 70, each having one or more reference points 64 and 74, respectively. In one embodiment, the masks 60 and/or the substrates 70 each have at least three reference points 64, 74. The alignment system 230 illustrated in FIG. 2 having one or more cameras may be used to visually align reference points 64 on the mask 60 with the reference points 74 on the substrates 70 to ensure proper placement of the mask 60 on the substrate 70.

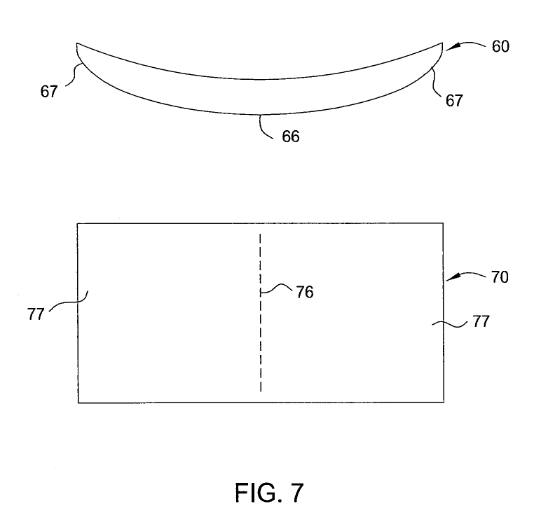

FIG. 7 illustrates a process of positioning a mask 60 on a substrate 70 according to one embodiment. The mask 60 is shown in an exaggerated bent or curved position to illustrate that a center point 66 of the mask 60 may be arranged to contact a center point 76 on the substrate 70 prior to the edges 67 contacting the edges 77 of the substrate 70. The portions of the mask 60 between the center point 66 and the edges 67 may push the air outward away from the center as the mask 60 begins to contact the substrate 70. In this manner, any potential air pockets may be prevented from developing between the mask 60 and the substrate 70, which may otherwise cause the mask 60 to move relative to the substrate 70 and thereby create a misalignment therebetween.

In one embodiment, the chuck 215, 315 may include a non-planar contact surface (e.g. concave or convex surface) relative to the substrate 70 to facilitate positioning of the mask 60 on the substrate 70. In one embodiment, the chuck 215, 315 may include an inclined contact surface relative to the substrate 70 to facilitate positioning of the mask 60 on the substrate 70. In one embodiment, the surface portions of the chuck 215, 315 that engage the mask 60 may be formed with a curved (concave) surface to bend the mask 60 so that the center point 66 contacts the substrate 70 prior to the edges 67 contacting. In one embodiment, the electromagnets 217, 317 of the chucks 215, 315 that engage the mask 60 adjacent the center point 66 may be deactivated prior to the electromagnets 217, 317 adjacent to the edges 67 to release the mask 60 so that the center point 66 contacts the substrate 70 prior to the edges 67 contacting. In one embodiment, the chucks 215, 315 may be configured to position the mask 60 on the substrate 70 such that the edges 67 contact the substrate 70 prior to the center point 66. In one embodiment, the chucks 215, 315 may be configured to sequentially release the mask 60 starting from a specific point, such as at a corner or edge of the mask 60, onto the substrate 70. In one embodiment, the chucks 215, 315 may be configured to remove the mask 60 from the substrate 70 in the same manner or in a reverse manner as when the mask 60 is initially positioned on the substrate 70.

While the foregoing is directed to embodiments of the invention, other and further embodiments of the invention may be devised without departing from the basic scope thereof, and the scope thereof is determined by the claims that follow.

1. A system for handling masked substrates, comprising:
a chamber having a pedestal for supporting a substrate, and a chuck for supporting a mask in relation to a substrate; and
an alignment system operable to confirm alignment of the mask and the substrate.

2. The system of claim 1, wherein the alignment system is operable to detect one or more reference points on the substrate and on the mask, and calculate a position of the reference points relative to a fixed coordinate system to assist in alignment of the mask and the substrate to one another.

3. The system of claim 2, wherein the alignment system is operable to communicate directional coordinates to at least one of the pedestal and the chuck, and wherein the at least one pedestal and chuck are operable to move the substrate, the mask, or both to align the reference points.

4. The system of claim 3, wherein the alignment system includes at least three cameras for detecting at least three reference points on the substrate and the mask.

5. The system of claim 1, wherein the chuck is an electromagnetic chuck having one or more electromagnets configured to move the mask with respect to a plane of the substrate, and wherein the surfaces of the electromagnets are coated with a soft material and the soft material selectively contacts the mask.

6. The system of claim 1, wherein the chuck is a vacuum chuck having one or more vacuum cups configured move the mask with respect to a plane of the substrate, and wherein the surfaces of the vacuum cups are coated with a soft material and the soft material selectively contacts the mask.

7. The system of claim 1, wherein the chamber comprises a body, an upper chamber, and a lower chamber, wherein the chuck and the pedestal are disposed in the upper chamber, and wherein the lower chamber comprises one or more support members for storing masks that are supported on carriers.

8. A method of positioning a mask on a substrate in a chamber, comprising:
supporting the mask with a chuck disposed in the chamber;
supporting the substrate with a pedestal disposed in the chamber;
aligning one or more reference points on the mask with one or more reference points on the substrate; and
positioning the mask on the substrate using at least one of the chuck and the pedestal.

9. The method of claim 8, wherein the chuck is one of an electromagnetic chuck and a vacuum chuck, each having one or more engagement members operable to engage and support the mask, and wherein the surfaces of the engagement members that contact the mask are coated with a soft material.

10. The method of claim 9, wherein the engagement members comprise at least one of electromagnets, electromagnetic strips, vacuum cups, and suction holes.

11. The method of claim 10, further comprising positioning the mask on the substrate using the engagement members by placing a center portion of the mask into contact with the substrate prior to an outer portion of the mask.

12. The method of claim 11, wherein the one of the electromagnetic chuck and the vacuum chuck includes a non-planar surface relative to a surface of the substrate that the mask is positioned on.

13. The method of claim 11, further comprising releasing the center portion of the mask from one or more of the engagement members prior to releasing the outer portion.

14. The method of claim 8, further comprising detecting the one or more reference points on the mask and the substrate using one or more cameras, calculating a position of the one or more reference points on the mask and the substrate relative to a fixed coordinate system to assist in aligning the mask and the substrate, and moving at least one of the mask with the chuck and the substrate with the pedestal to align the one or more reference points on the mask and the substrate.

15. The method of claim 8, further comprising performing a deposition process on the substrate after positioning the mask on the substrate, and removing the mask from the substrate after performing the deposition process.

16. The method of claim 15, further comprising moving the mask into the chamber on a carrier and then lifting the mask from the carrier using the chuck.

17. The method of claim 15, further comprising positioning the mask on a carrier and moving the mask and the carrier to another chamber, and further comprising cleaning the mask and the carrier.

18. A method of handling a mask and a substrate, comprising:
positioning the mask on the substrate in a first chamber;
processing the substrate while the mask is positioned on the substrate in a second chamber;
removing the mask from the substrate after processing the substrate in a third chamber;
positioning the mask on a carrier in the third chamber; and
cleaning the mask on the carrier in a fourth chamber.

19. The method of claim 18, wherein the first chamber and the fourth chamber are formed from a chamber body, such that the first chamber is an upper chamber of the chamber body and the fourth chamber is a lower chamber of the chamber body.

20. The method of claim 18, wherein the third chamber and the fourth chamber are formed from a chamber body, such that the third chamber is an upper chamber of the chamber body and the fourth chamber is a lower chamber of the chamber body.
